(19) United States
(12) Patent Application Publication
(10) Pub. No.: US 2010/0078204 A1
(43) Pub. Date: Apr. 1, 2010

(54) Printed circuit board including electronic component embedded therein and method of manufacturing the same

(75) Inventors: Hong Bok We, Gyunggi-do (KR); Tae Sung Jeong, Gyunggi-do (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/320,012

(22) Filed: Jan. 14, 2009

(30) Foreign Application Priority Data
Sep. 29, 2008 (KR) 10-2008-0095455

(51) Int. Cl. H05K 1/00; H05K 3/00; H05K 3/30

(52) U.S. Cl. 174/260; 29/829; 29/832

(57) ABSTRACT

Disclosed herein is a printed circuit board including an electronic component embedded therein and a method of manufacturing the printed circuit board. The electronic component is disposed in a cavity of a resin layer including circuit layers formed on both sides thereof. The resin layer, the electronic component and the circuit layers are attached to each other via adhesive layers disposed therebetween. The printed circuit board is manufactured by a compression process, thus shortening a production time and simplifying a manufacturing process.

### CROSS REFERENCE TO RELATED APPLICATION

This application claims the benefit of Korean Patent Application No. 10-2008-0095455, filed Sep. 29, 2008, entitled “PRINTED CIRCUIT BOARD WITH ELECTRONIC COMPONENTS EMBEDDED THEREIN AND METHOD FOR FABRICATING THE SAME”, which is hereby incorporated by reference in its entirety into this application.

### BACKGROUND OF THE INVENTION

1. Field of the Invention

The present invention relates to a printed circuit board including an electronic component embedded therein and a method of manufacturing the same.

2. Description of the Related Art

These days, in response to the miniaturization and the reduction in the weight of electronic products, printed circuit boards, which include electronic components such as semiconductor elements embedded therein, are getting a lot of attention.

In order to realize a printed circuit board including electronic components embedded therein, there exists a wide variety of surface-mounting technologies for mounting semiconductor devices such as Integrated Circuit (IC) chips on a printed circuit board. The surface-mounting technologies may include a wire bonding technology and a flip chip technology.

Among these, a surface-mounting process using the wire bonding technology is configured in a manner such that an electronic component, on which a designed circuit is printed, is bonded on a printed circuit board using adhesive, metal terminals (i.e., pads) of the electronic component are connected to lead frames of the printed circuit board via metal wires for the transmission of information therebetween, and the electronic component and the wires are subjected to a molding process using thermosetting resin or thermoplastic resin.

Meanwhile, a surface-mounting process using the flip chip technology is configured in a manner such that external connecting terminals (i.e., bumps) having a size ranging from several tens μm to hundreds of μm are formed on an electronic component using connecting materials such as gold, solder and other metals, the electronic component including the bump formed thereon is flipped over so that the surface of the component faces a printed circuit board, and the electronic component is mounted on the printed circuit board in the flipped orientation, unlike the process using the wire bonding technology.

Since these surface-mounting processes are conducted in a common manner in which an electronic component is mounted on the surface of a printed circuit board, the total thickness of the resulting product after the mounting process cannot be less than the sum of thicknesses of the printed circuit board and the electronic component, thus making the manufacture of a high-density product difficult. In addition, since electrical connection between the electronic component and the printed circuit board is achieved using the connecting terminals (pads or bumps), the electrical connection may be damaged or may malfunction due to breakage or corrosion of the connecting terminals, thus deteriorating the reliability of the product.

For this reason, in order to overcome the above problems, electronic components are embedded inside rather than outside the printed circuit, and a build-up layer is formed for the electrical connection, thereby realizing compact and high-density products, minimizing a wiring distance at a high frequency (100 MHz or higher), and avoiding the deterioration in reliability occurring at a stage of connecting components to each other in the surface-mounting process using the wire bonding technology or the flip chip technology.

FIGS. 1 to 7 are cross-sectional views showing a conventional process of manufacturing a printed circuit board including an electronic component embedded therein. Referring to the drawings, the conventional process is now described.

First, as shown in FIG. 1, a core substrate 10, which is comprised of a copper clad laminate and an internal circuit layer 11 formed on the copper clad laminate, in which a cavity 12 for receiving an electronic component therein is formed in the copper clad laminate, is prepared.

As shown in FIG. 2, tape 13, which serves to support an electronic component, is attached to one side of the core substrate 10.

As shown in FIG. 3, an electronic component 14 having electrode terminals 15 thereon is placed in the cavity 12, and is then attached to the tape 13 in a face-up orientation.

As shown in FIG. 4, thereafter, a first insulating layer 16 is formed on the other side of the core substrate 10 on which the tape 13 is not attached, and is also formed in a gap between the electronic component 14 and the inner wall of the cavity 12.

As shown in FIG. 5, the tape 13 is removed from the one side of the core substrate 10.

As shown in FIG. 6, a second insulating layer 17 is formed on the other side of the core substrate 10 from which the tape 13 is removed.

As shown in FIG. 7, finally, an external circuit layer 18, which has vias 19 connected to the internal circuit layer 11 or the electrode terminals 15 of the electronic component 14, is formed on the first insulating layer 16 and the second insulating layer 17.

However, the process, which is intended to embed the electronic component 14 in the printed circuit board using the conventional technology, inevitably requires the tape 13, which is used to support the electronic component 14 only during the process, the use of the support tape 13 causes increase in the productions cost. In addition, the taping process of attaching and detaching the tape 13 causes the manufacturing process to be complicated.

Furthermore, since the process is conducted in a manner such that the electronic component 14 is supported by the tape 13, the first insulating layer 16 is formed on the other side of the core substrate 10 on which the tape 13 is not attached, the tape 13 is removed and then the second insulating layer 17 is formed on the one side of the core substrate 10, the period of time required in the process is disadvantageously prolonged.

In addition to these, since additional processes of forming the cavity 12 for accommodating the electronic component 14 using laser and the like and fixing the electronic component 14 in the cavity 12 are required, there are problems of increase in the number of processes and the processing time.

### SUMMARY OF THE INVENTION

Accordingly, the present invention has been made keeping in mind the above problems occurring in the prior art, and the present invention provides a printed circuit board including an electronic component embedded therein and a method of manufacturing the same, which is configured to enable the reduction in processing time and production costs and the easy mass production.

In one aspect, the present invention provides a printed circuit board including an electronic component embedded therein, including: a resin layer having a cavity formed therein; an electronic component embedded in the cavity; circuit layers formed on both sides of the resin layer; and adhesive layers disposed between the circuit layers and the resin layer and in the cavity to attach the resin layer, the electronic component and the circuit layers to each other.

The circuit layers may include a via connected an electrode terminal of the electronic component.

The adhesive layers may be disposed between the electronic component and the resin layer within the cavity.

In another aspect, the present invention provides a method of manufacturing a printed circuit board including an electronic component embedded therein, the method including: (A) preparing a first carrier part composed of a first metal layer, a first adhesive layer applied on one side of the metal layer and an electronic component attached to the first metal layer, a resin layer, and a second carrier part composed of a second metal layer and a second adhesive layer applied on one side of the second metal layer; (B) positioning the first and second metal layers and the resin layer such that the one side of the first metal layer faces the one side of the second metal layer with the resin layer being disposed between the first and second metal layers, and then compressing the first and second metal layers and the resin layer together; and (C) patterning the first and second metal layers to form circuit layers.

The resin layer may be made of polyimide resin or epoxy resin.

In (A) preparing the first and second carrier parts and the resin layer, the resin layer may include a cavity in which the electronic component is disposed.

The cavity may be formed using a punching operation.

In (B) compressing the first and second metal layers and the resin layer together, the compression is conducted through a reel-to-reel or roll-to-roll process using compression rollers.

In (C) patterning the first and second metal layers, the circuit layers may include a via connected to an electrode terminal of the electronic component.

In still another aspect, the present invention provides a method of manufacturing a printed circuit board including an electronic component embedded therein, the method including: (A) preparing a first carrier part composed of a first metal layer, a first adhesive layer applied on one side of the metal layer, a resin layer having a cavity and attached to the first metal layer, and an electronic component attached to the first metal layer within the cavity, and a second carrier part composed of a second metal layer and a second adhesive layer applied on one side of the second metal layer; (B) positioning the first and second metal layers such that the one side of the first metal layer faces the one side of the second metal layer, and then compressing the first and second metal layers together; and (C) patterning the first and second metal layers to form circuit layers.

The resin layer may be made of polyimide resin or epoxy resin.

The cavity may be formed using a punching operation.

In (B) compressing the first and second metal layers together, the compression may be conducted through a reel-to-reel or roll-to-roll process using compression rollers.

In (C) patterning the first and second metal layers, the circuit layers may include a via connected to an electrode terminal of the electronic component.

In a further aspect, the present invention provides a method of manufacturing a printed circuit board including an electronic component embedded therein, the method including: (A) preparing a first carrier part composed of a first metal layer, a first adhesive layer applied on one side of the metal layer, and an electronic component attached to the first metal layer, and a second carrier part composed of a second metal layer and a second adhesive layer applied on one side of the second metal layer; (B) positioning the first and second metal layers such that the one side of the first metal layer faces the one side of the second metal layer, and then compressing the first and second metal layers together; and (C) patterning the first and second metal layers to form circuit layers.

The resin layer may be made of polyimide resin or epoxy resin.

In (A) preparing the first and second carrier parts, the resin layer may include a cavity in which the electronic component is disposed.

The cavity may be formed using a punching operation.

In (B) compressing the first and second metal layers together, the compression may be conducted through a reel-to-reel or roll-to-roll process using compression rollers.

In (C) patterning the first and second metal layers, the circuit layers may include a via connected to an electrode terminal of the electronic component.

### BRIEF DESCRIPTION OF THE DRAWINGS

The above and other objects, features and other advantages of the present invention will be more clearly understood from the following detailed description taken in conjunction with the accompanying drawings, in which:

FIGS. 1 to 7 are cross-sectional views showing a conventional process of manufacturing a printed circuit board, including electronic components embedded therein;

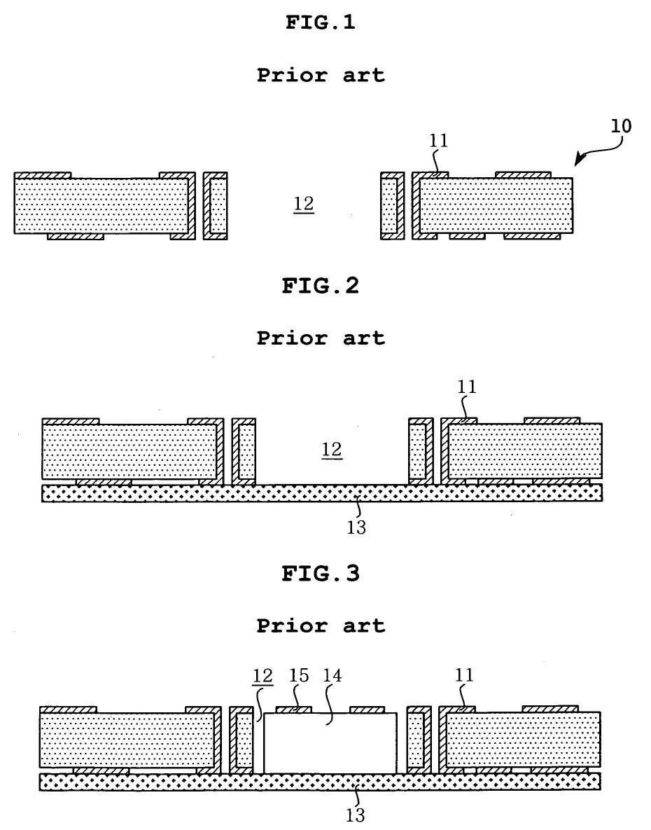

FIG. 8 is a cross-sectional view of a printed circuit board including electronic components embedded therein, according to a first embodiment of the present invention;

FIGS. 9 to 13 are cross-sectional views showing a process of manufacturing a printed circuit board including electronic components embedded therein, according to the first embodiment of the present invention;

FIG. 14 is a cross-sectional view showing a process of manufacturing a printed circuit board including electronic components embedded therein, according to a second embodiment of the present invention;

FIG. 15 is a cross-sectional view showing a process of manufacturing a printed circuit board including electronic components embedded therein, according to a third embodiment of the present invention;

FIG. 16 is a side view showing a compression process according to the first embodiment of the present invention; and

FIG. 17 is a side view showing compression processes according to the second and third embodiments of the present invention.

### DESCRIPTION OF THE PREFERRED EMBODIMENTS

Various objects, advantages and features of the invention will become apparent from the following description of embodiments with reference to the accompanying drawings. In the following detailed description, it should be noted that the terms “first”, “second” and the like are not intended to indicate a specified amount, sequence or significance but intended to differentiate constituent elements. Furthermore, in designation of reference numerals, it should be noted that the same reference numerals are used throughout the different drawings to designate the same or similar components. Also, in the description of the present invention, when it is considered that the detailed description of a related prior art may obscure the gist of the present invention, such detailed description may be omitted.

Hereinafter, embodiments of the present invention will be described in greater detail with reference to the following drawings.

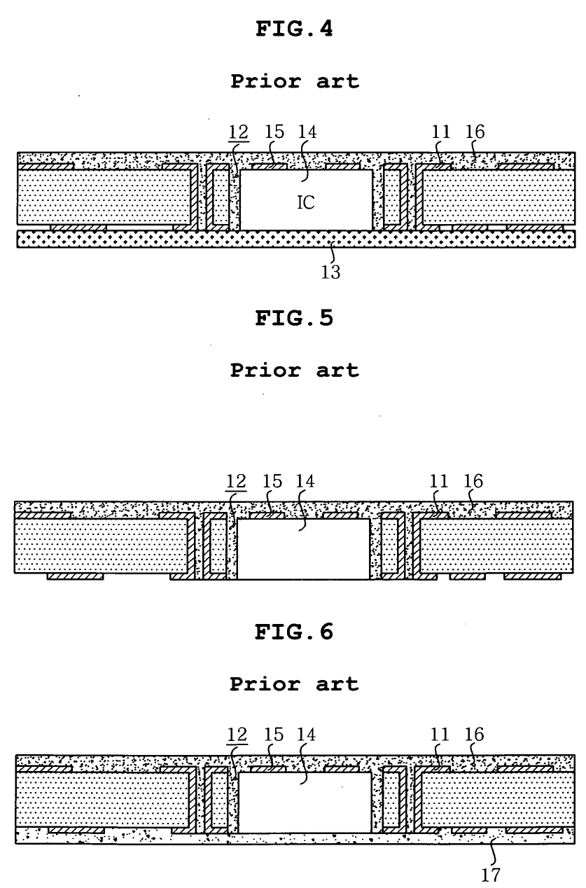

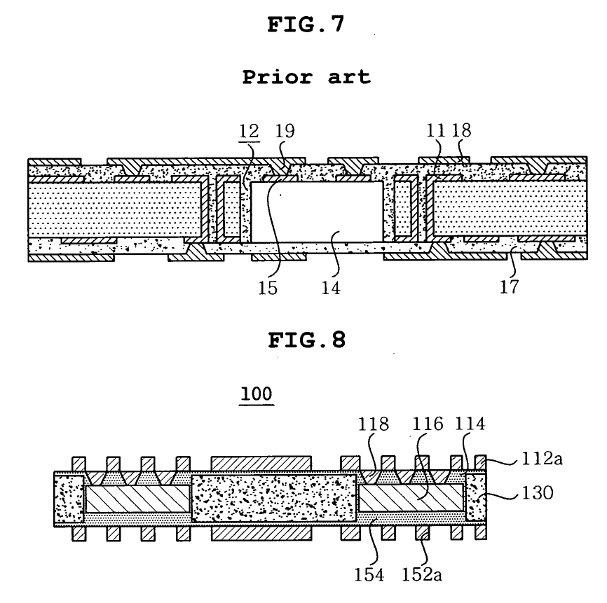

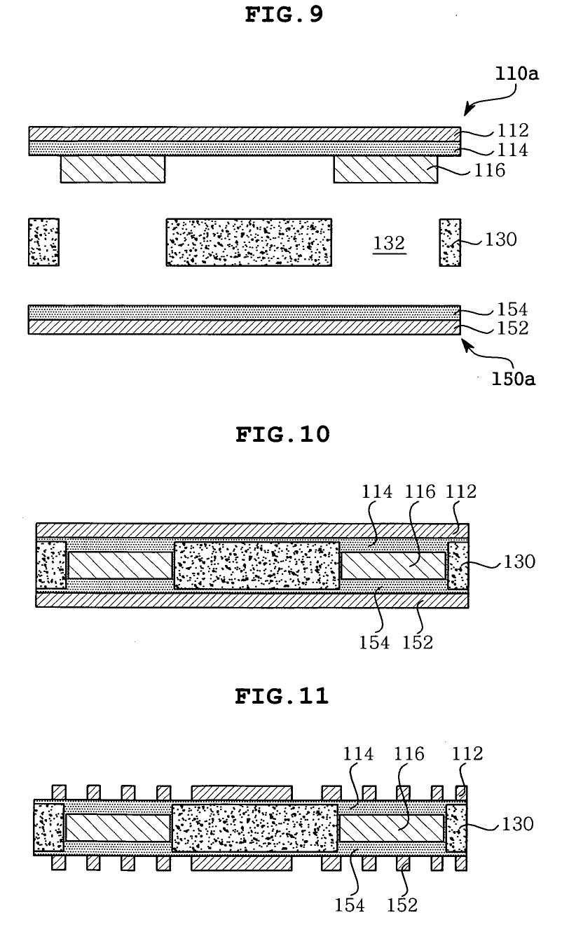

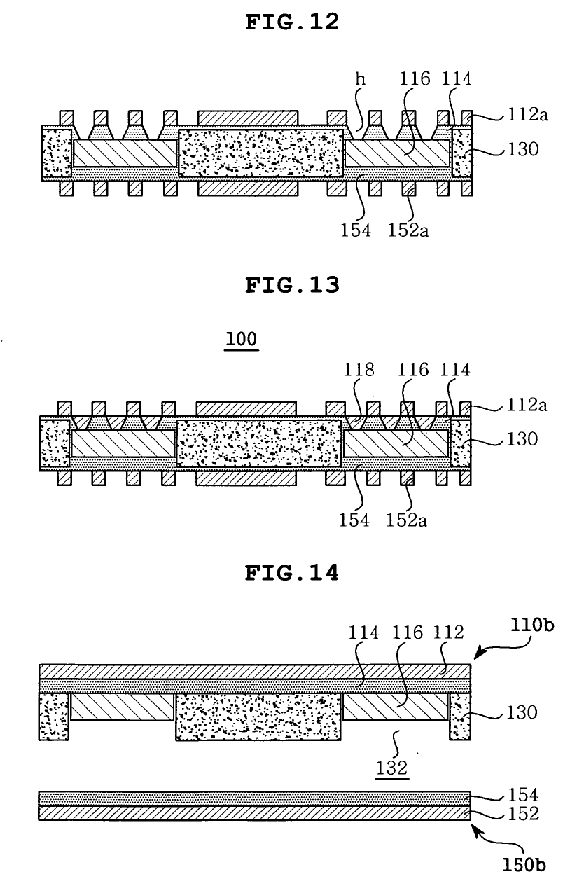

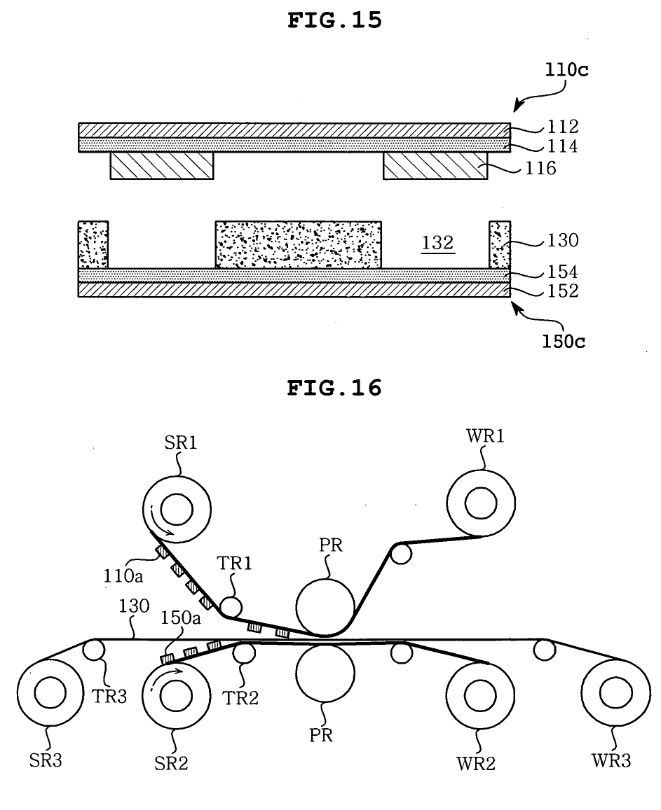

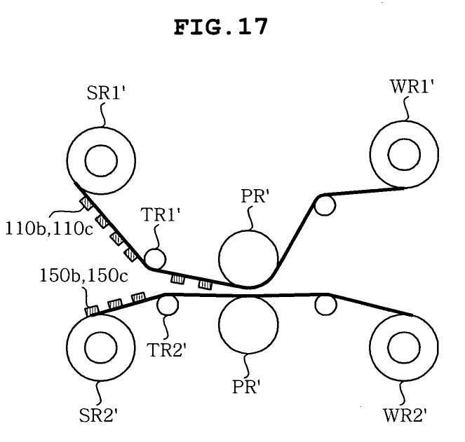

FIG. 8 is a cross-sectional view of a printed circuit board including an electronic component embedded therein, according to an embodiment of the present invention, FIGS. 9 to 13 are cross-sectional views showing a method of manufacturing a printed circuit board including an electronic component therein, according to a first embodiment of the present invention, FIG. 14 is a cross-sectional view showing a method of manufacturing a printed circuit board including an electronic component therein, according to a second embodiment of the present invention, FIG. 15 is a cross-sectional view showing a method of manufacturing a printed circuit board including an electronic component therein, according to a third embodiment of the present invention, FIG. 16 is a view showing a compression process according to a first embodiment of the present invention, and FIG. 17 is a view showing compression processes according to second and third embodiments of the present invention.

Referring to FIG. 8, a printed circuit board 100 including electronic components embedded therein, according to an embodiment of the present invention, will now be described.

The printed circuit board 100 according to an embodiment of the present invention includes electronic components 116 embedded in cavities 132 of a resin layer 130 on both sides of which circuit layers are formed, in which the reins layer 116, the electronic components 116 and the circuit layers 112a, 152a are attached to each other via adhesive layers 114, 154 disposed therebetween.

The adhesive layers 114, 154 are disposed between the circuit layers 112a, 152a and the resin layer 130 in order to attach them to each other, are disposed between the electronic components 116 and the circuit layers 112a, 152a in order to attach them to each other, and are at the same time disposed between the electronic components 116 in the cavities 132 and the resin layers 130 in order to attach them to each other.

The circuit layers 112a, 152a further include vias 118 for the connection with electrode terminals (not shown) of the electronic components 116.

Referring to FIGS. 9 to 13, a method of manufacturing a printed circuit board including electronic components embedded therein, according to a first embodiment of the present invention, will now be described.

As shown in FIG. 9, a first carrier part 110a and a second carrier part 150a are first prepared, in which the first carrier part 110a is composed of a first metal layer 112 and a first adhesive layer 114 applied on the first metal layer 112 with electronic components 116 being attached to the first metal layer 112, and the second carrier part 150a is composed of a second metal layer 152 and a second adhesive layer 154 applied on the second metal layer 152.

The first carrier part 110a, which is intended to provide the first metal layer 122 for forming a circuit layer and the electronic components 116, is prepared in a manner such that the first adhesive layer 114 is applied on one side of the first metal layer 112 and then the electronic components 116 are attached to desired positions on the first metal layer 112. In an embodiment, the first adhesive layer 114 applied on the first metal layer 112 may applied on the entire surface of one side of the first metal layer 112 so as to ensure the easy attachment of the electronic components 116 and the resin layer 130 to the first metal layer 112.

In an embodiment, the resin layer 130, which is intended to provide an interlayer insulating layer, may have a height equal to or higher than a height of the electronic components 116, and may have cavities 132 which is formed in advance for accommodating the electronic components therein. In this context, although the electronic components 116 may be embedded in the resin layer 130 by compressing the electronic components 116 into the resin layer 130 which is semicured and has no cavity, the electronic components may be embedded in the cavities 132 which is formed in advance in the resin layer 130 in order to prevent damage to the electronic components 116 caused by the press and to position the electronic components at desired locations for the easy connection with a circuit layer. In this regard, the cavities 132 may be formed using mechanical/laser drilling and the like such that they have dimensions equal to or greater than the electronic components, and may be positioned at locations corresponding to the electronic components 116 attached to the layer 112. In particular, the cavities 132 may be conveniently formed in the resin layer 130, which is transferred by a supply reel or a take-up reel, through a punching operation in a reel-to-reel process or a roll-to-roll process which is to be described later.

The resin layer 130 may be composed of insulating resin such as polyimide resin or epoxy resin.

The electronic components 116 may be of active elements as well as passive elements.

The second carrier part 150a, which is intended to provide the second metal layer 152 for forming a circuit layer, is composed of the second metal layer 152 and the second adhesive layer 154 applied on one side of the second metal layer 152.

Since the first metal layer 112 and the second metal layer 152 are patterned in a post process and thus serves as circuit layers, the first and second metal layers 112, 152 may be composed of copper film.

As shown in FIG. 10, the first metal layer 112 and the second metal layer 152 are oriented such that the lower surface of the first metal layer 112 faces the upper surface of the second metal layer 152 with the resin layer 130 being disposed therebetween, and compressed and thus attached to each other.

At this point, the electronic components 116 on the first carrier part 110 is positioned in the cavities 132 of the resin layer 130, and the first adhesive layer 114 and the second adhesive layer 154 are penetrated into gaps between the electronic components 116 and the internal surfaces of the cavities 132 as well as being placed on upper and lower surfaces of the electronic components 116 through the compression operation, thus attaching the first and second carrier parts 110a, 150a to the resin layer 130.

In the compression operation, a reel-to-reel process or a roll-to-roll process, which is to be described later, may be employed.

As shown in FIG. 11, the first metal layer 112 and the second metal layer 152 are patterned thus forming a first circuit layer 112a and a second circuit layer 152a, respectively.

In this regard, the first circuit layer 112a and the second circuit layer 152a may be formed using a known circuit formation process such as a subtractive process.

As shown in FIG. 12, via-holes h are formed in the first adhesive layers 114 to allow the connection of electrode terminals (not shown) of the electronic components 116 with the circuit layers. Referring to FIG. 12, although the electronic components 116 are shown as being mounted in a face-up orientation so that the via-holes h are formed to connect the electrode terminals to the first circuit layer 112a, it is no more than illustration of an example and it is also possible to mount the electronic components in a face-down orientation.

As shown in FIG. 13, finally, a plating layer is applied in the via-holes h to form vias 118 for the connection of the electrode terminals of the electronic components 116 with the first and second circuit layers 112a, 152a.

Although it is not shown in the drawings, a multilayer printed circuit board may also be manufactured by providing vias or bumps to the printed circuit board including the electronic components 116 embedded therein as shown in FIG. 13.

Referring to FIG. 14, a method of manufacturing a printed circuit board including electronic components embedded therein, according to a second embodiment of the present invention, will now be described.

This embodiment differs from the above first embodiment in that the resin layer is previously attached to the first carrier part for the accurate matching of the first and second carrier layers, that is, there is a difference between the constructions of the carrier parts. With the exception of this difference, the other constituent elements and processes are substantially identical to those of the first embodiment, and thus only the construction of the carrier according to the second embodiment will be described below without the redundant description of the identical elements.

More specifically, the carrier according to this embodiment of the present invention includes a first carrier part 110b and a second carrier part 150b, in which the first carrier part 110b is composed of a first metal layer 112, a first adhesive layer 114 applied on a lower surface of the first metal layer 112, a resin layer 130 having cavities 132, and electronic components 116 embedded in the cavities 132, and the second carrier part 150b is composed of a second metal layer 152 and a second adhesive layer 154 applied on an upper surface of the second metal layer 152. In this regard, since the second carrier part 150b is substantially identical to the second carrier part 150b according to the first embodiment as shown in FIG. 9, a detailed description thereof is omitted herein.

The first carried part 110b may be prepared in such a way as to attach the electrode components 116 and the resin layer 130 having cavities 132 for accommodating the electrode components 116 to the first metal layer 112 on which the first adhesive layer 114 is applied. At this point, the cavities 132 may be formed through a mechanical/laser drilling operation or a punching operation.

Alternatively, the first carrier part 110b may also be formed in another way as to prepare a single-sided copper clad laminate having cavities 132 and to attach the electronic components 116 to the copper clad laminate within the cavities 132 via the first adhesive layer 114. In this case, there is a difference in that the first adhesive layer 114 is provided only to regions between the electronic components 116 and the first metal layer 112.

The first carrier part 110b and the second carrier part 150b, which are manufactured in the above-describe manner, are subjected to the compression process and the circuit layer-forming process as shown in FIGS. 10 to 13, thus providing the printed circuit board including electronic components embedded therein. The redundant description of the process is omitted herein.

In this embodiment, a compression process or a reel-to-reel or roll-to-roll process using compression rollers may be employed, which will be described later.

Referring to FIG. 15, a method of manufacturing a printed circuit board including electronic components embedded therein, according to a third embodiment of the present invention, will now be described.

This embodiment differs from the above first embodiment in that the resin layer is previously attached to the second carrier part, that is, there is a difference between the constructions of the carrier parts. With the exception of this difference, the other constituent elements and processes are substantially identical to those of the first embodiment, and thus only the construction of the carrier according to the third embodiment will be described below without the redundant description of the identical elements.

More specifically, the carrier according to this embodiment of the present invention includes a first carrier part 110c and a second carrier part 150c, in which the first carrier part 110c is composed of a first metal layer 112, a first adhesive layer 114 applied on a lower surface of the first metal layer 112, and electronic components 116 attached to the first metal layer 112, and the second carrier part 150c is composed of a second metal layer 152, a second adhesive layer 154 applied on an upper surface of the second metal layer 152, and a resin layer 130 attached to the second metal layer 152. In this regard, since the first carrier part 110c is substantially identical to the first carrier part 110a according to the first embodiment as shown in FIG. 9, a detailed description thereof is omitted herein.

The second carried part 150c may be prepared in such a way as to attach the resin layer 130 having cavities 132 to the second metal layer 152 on which the second adhesive layer 154 is applied. At this point, the cavities 132 may be formed through a mechanical/laser drilling operation or a punching operation.

Alternatively, the second carrier part 150c may also be formed in another way as to prepare a single-sided copper clad laminate composed of the second metal layer 152 and the resin layer 130 applied to one side of the second metal layer 152 and to form the cavities 132 for accommodating the electronic components in the single-sided copper clad laminate. In this case, there is a difference in that the process of separately applying the second adhesive layer 154 is omitted.

The first carrier part 110c and the second carrier part 150c, which are manufactured in the above-describe manner, are subjected to the compression process and the circuit layer-forming process as shown in FIGS. 10 to 13, thus providing the printed circuit board including electronic components embedded therein. The redundant description of the process is omitted herein.

In this embodiment, a compression process or a reel-to-reel or roll-to-roll process using compression rollers may be employed, which will be described later.

Referring to FIGS. 16 and 17, compression processes according to the first to third embodiments of the present invention are now described.

As previously described, processes of compressing carrier parts, according to the first to third embodiments of the present invention may employ a reel-to-reel process or a roll-to-roll process which uses compression rollers.

Referring first to FIG. 16, a compression process according to the first embodiment of the present invention is conducted in a manner such that the first carrier part 110a, the resin layer 130 and the second carrier part 150a are transferred between supply reels and take-up reels and are compressed together while passing through compression rollers PR disposed between the supply reels and the take-up reels.

More specifically, the first carrier part 110a, the second carrier part 150a and the resin layer 130 are transferred from the first to third supply reels SR1, SR2, SR3 to the first to third take-up reels WR1, WR2, WR3, respectively. At this time, the first carrier part 110a, the second carrier part 150a and the resin layer 130 are arranged parallel to each other by first to third tension control rollers TR1, TR2, TR3, respectively, and are then compressed together while passing through a pair of compression roller PR.

In the case of employing such a reel-to-reel/roll-to-roll process, a mechanical alignment can be achieved, thus obviating the need for additional align marks and ensuring reduction of a process time and commercial production.

Referring to FIG. 17, processes of compressing the first carrier part 110 and the second carrier part 150 through a reel-to-reel or roll-to-roll process using compression rollers, according to the second and third embodiments of the present invention will now be described.

The second and third embodiments differ from the first embodiment in that an additional drive reel for driving a resin layer is not used because a carrier part is configured to have a resin layer attached thereto.

More specifically, the first carrier part 110b, 110c and the second carrier part 150b, 150c are transferred from the first to third supply reels SR1′, SR2′ to the first to third take-up reels WR1′, WR2′, respectively. At this time, the first carrier part 110b, 110c and the second carrier part 150b, 150c are arranged parallel to each other by first and second tension control rollers TR1′, TR2′, respectively, and are then compressed together while passing through a pair of compression roller PR′.

As described above, the present invention produces a printed circuit board including an electronic component embedded therein, by compressing carrier parts, and thus a taping process may be obviated, thus shortening a production time and simplifying a manufacturing process.

Furthermore, since a cavity can be formed in a resin layer through a punching operation, a production time required for the formation of the cavity is reduced.

In addition, since the present invention produces a printed circuit board including an electronic component embedded therein, through a reel-to-reel or roll-to-roll process, the printed circuit boards can be easily produced in large numbers. Furthermore, since an aligning function of the reel-to-reel or roll-to-roll process itself is employed in the production, there is no need for provision of additional align marks.

Although the preferred embodiments of the present invention have been disclosed for illustrative purposes, those skilled in the art will appreciate that various modifications, additions and substitutions are possible, without departing from the scope and spirit of the invention as disclosed in the accompanying claims. Accordingly, such modifications, additions and substitutions should also be understood to fall within the scope of the present invention.

1. A printed circuit board including an electronic component embedded therein, comprising:
a resin layer having a cavity formed therein;
an electronic component embedded in the cavity;
circuit layers formed on both sides of the resin layer; and
adhesive layers disposed between the circuit layers and the resin layer and in the cavity to attach the resin layer, the electronic component and the circuit layers to each other.

2. The printed circuit board according to claim 1, wherein the circuit layers include a via connected an electrode terminal of the electronic component.

3. The printed circuit board according to claim 1, wherein the adhesive layers are disposed between the electronic component and the resin layer within the cavity.

4. A method of manufacturing a printed circuit board including an electronic component embedded therein, the method comprising:
preparing a first carrier part composed of a first metal layer, a first adhesive layer applied on one side of the metal layer and an electronic component attached to the first metal layer, a resin layer, and a second carrier part composed of a second metal layer and a second adhesive layer applied on one side of the second metal layer;
positioning the first and second metal layers and the resin layer such that the one side of the first metal layer faces the one side of the second metal layer with the resin layer being disposed between the first and second metal layers, and then compressing the first and second metal layers and the resin layer together; and
patterning the first and second metal layers to form circuit layers.

5. The method according to claim 4, wherein the resin layer is made of polyimide resin or epoxy resin.

6. The method according to claim 4, wherein, in preparing the first and second carrier parts and the resin layer, the resin layer includes a cavity in which the electronic component is disposed.

7. The method according to claim 6, wherein the cavity is formed using a punching operation.

8. The method according to claim 4, wherein, in compressing the first and second metal layers and the resin layer together, the compression is conducted through a reel-to-reel or roll-to-roll process using compression rollers.

9. The method according to claim 4, wherein, in patterning the first and second metal layers, the circuit layers include a via connected to an electrode terminal of the electronic component.

10. A method of manufacturing a printed circuit board including an electronic component embedded therein, the method comprising:
preparing a first carrier part composed of a first metal layer, a first adhesive layer applied on one side of the metal layer, a resin layer having a cavity and attached to the first metal layer, and an electronic component attached to the first metal layer within the cavity, and a second carrier part composed of a second metal layer and a second adhesive layer applied on one side of the second metal layer;
positioning the first and second metal layers such that the one side of the first metal layer faces the one side of the second metal layer, and then compressing the first and second metal layers together; and
patterning the first and second metal layers to form circuit layers.

11. The method according to claim 10, wherein the resin layer is made of polyimide resin or epoxy resin.

12. The method according to claim 10, wherein the cavity is formed using a punching operation.

13. The method according to claim 10, wherein, in compressing the first and second metal layers together, the compression is conducted through a reel-to-reel or roll-to-roll process using compression rollers.

14. The method according to claim 10, wherein, in patterning the first and second metal layers, the circuit layers include a via connected to an electrode terminal of the electronic component.

15. A method of manufacturing a printed circuit board including an electronic component embedded therein, the method comprising:
preparing a first carrier part composed of a first metal layer, a first adhesive layer applied on one side of the metal layer, and an electronic component attached to the first metal layer, and a second carrier part composed of a second metal layer and a second adhesive layer applied on one side of the second metal layer;
positioning the first and second metal layers such that the one side of the first metal layer faces the one side of the second metal layer, and then compressing the first and second metal layers together; and
patterning the first and second metal layers to form circuit layers.

16. The method according to claim 15, wherein the resin layer is made of polyimide resin or epoxy resin.

17. The method according to claim 15, wherein in preparing the first and second carrier parts, the resin layer includes a cavity in which the electronic component is disposed.

18. The method according to claim 17, wherein the cavity is formed using a punching operation.

19. The method according to claim 15, wherein, in compressing the first and second metal layers together, the compression is conducted through a reel-to-reel or roll-to-roll process using compression rollers.

20. The method according to claim 15, wherein, in patterning the first and second metal layers, the circuit layers include a via connected to an electrode terminal of the electronic component.
